(19) United States
(12) Patent Application Publication
(10) Pub. No.: US 2007/0063758 A1
(43) Pub. Date: Mar. 22, 2007

(54) Voltage divider and method for minimizing higher than rated voltages

(75) Inventors: Thaddeus A. Allard, Plymouth, MN (US); Keith W. Golke, Minneapolis, MN (US); Michael T. Johnson, Plymouth, MN (US); Karu Vignarajah, Elkridge, MD (US)

Correspondence Address: HONEYWELL INTERNATIONAL INC., 101 COLUMBIA ROAD, P O BOX 2245, MORRISTOWN, NJ, 07962-2245, US

(73) Assignee: Honeywell International Inc., Morristown, NJ (US)

(21) Appl. No.: 11/232,734

(22) Filed: Sep. 22, 2005

(51) Int. Cl. H03L 5/00

(52) U.S. Cl. 327/333

(57) ABSTRACT

A voltage divider circuit can be realized by dividing a higher than rated operating voltage across a plurality of MOS transistors. The voltage divider circuit can be used for a wide variety of ratios of low and high operating voltages. Only one gate input voltage is needed, minimizing power dissipation, heat, and hot carrier effects. The voltage divider circuit is employed in a voltage driver circuit to generate a high output voltage in response to a low voltage input while minimizing damage to the MOS transistors within the voltage driver circuit.

### STATEMENT REGARDING FEDERALLY SPONSORED RESEARCH

This invention was at least partially made with U.S. Government support under contract DTRA01-00-C-0017 awarded by the Defense Threat Reduction Agency. Accordingly, the government may possess certain rights in the invention.

### FIELD

The present invention relates generally to integrated circuits, and more particularly, to a circuit and a method that outputs a desired voltage while minimizing higher than rated voltages across MOS transistors.

### BACKGROUND

As CMOS technology advances, device sizes and areas continue to decrease, while performance (increased speed, decreased power consumption and heat dissipation, etc.) has improved. Correspondingly, transistor operating voltages have followed this trend. An example of this can be seen in the shift from operating at 5V to 3.3V and even 2.5V.

Despite the continuing trend to move to lower operating voltages, many circuit designers are still constrained to design circuits that are compatible with both high and low operating voltages. One such reason being that many established circuits, such as the ones found in standard design libraries, need to be implemented in a cost effective way. Redesigning a given circuit for a lower operating voltage may be too costly in terms of time or other financial considerations.

When trying to use two circuits with different operating voltages, often times a lower voltage transistor is used and operated at higher voltages. Despite this, using higher than rated voltages (i.e. a 5V supply on a 2.5V device) can cause many problems. Too high of an operating voltage applied to an individual transistor may result in damage and, as a consequence, an entire circuit might also be damaged. Two types of damage that frequently arise when a higher than rated voltage is applied across a transistor are hot carrier effects and transistor breakdown.

Although a low operating voltage transistor may be used with a higher operating voltage, it is quite difficult to produce a 5V output from a 2.5V operating voltage transistor. Circuit designers overcome this problem by employing output driver circuits. These circuits convert voltages from a low operating voltage value (2.5 V or 3.3V) to a higher operating voltage value (5V). The converted voltage can then be effectively applied to a circuit. One issue in creating these circuits, particularly when using technology that employs lower operating voltages, is that unless an output driver is designed properly, the transistors in the output driver itself are still exposed to high operating voltages which, as stated previously, may result in eventual circuit breakdown.

One such structure and method of reducing the amount of applied operating voltage, disclosed by Hynes in U.S. Pat. No. 6,518,818, has been to reduce the amount of voltage applied across the source and drain terminals of a lower operating voltage FET transistor. This can be seen in FIG. 1. In this figure, a series of two p-FETs are tied together at their respective source and drain connections. An overall input 102 (0V or 3.3V) is received by the circuit and an output voltage 104 indicative of the overall input to the circuit is output (0V for a 0V input, 5V for a 3.3V input). An input voltage 106 (in this case from a common node of two p-FETs) is input into the gate of a p-FET 108. If this FET could withstand a 5V drop from source to drain (as would be the case when the output 104 is at 0V and the drain voltage 105 is 5V) the second transistor 110 and the additional applied bias V_{REF} 112, would not be necessary. However, these components are necessary to produce a voltage, namely V_{REF} plus the threshold voltage Vₚ, at node 114 in order to reduce the overall voltage drop across a single transistor. Thus, the damaging effects of too high of an operating voltage across one transistor are reduced.

This method and circuit, and those similar to it, have a considerable drawback. This circuit necessitates an extra voltage source, namely V_{REF}. V_{REF} is continually applied to the gate of a MOS transistor; this results in static current dissipation leading to increased power consumption and heat dissipation. Thus, it would be desirable to provide a circuit and a method that outputs a desired voltage while minimizing higher than rated voltages across MOS transistors.

### SUMMARY

One embodiment provides for a voltage divider circuit comprised of a series of stacked MOS transistors. By dividing a higher than rated operating voltage across a plurality of MOS transistors, a higher than rated operated voltage can be effectively distributed across a series of MOS transistors. Only one gate input voltage is needed, eliminating the need for additional reference voltages. The voltage divider circuit presented in this application can be used for a wide variety of ratios of low and high operating voltages. The resultant circuit minimizes static current loss and power dissipation as well as reduces hot carrier effects. The voltage divider circuit is employed in a voltage driver circuit to generate a high output voltage in response to a low voltage input.

These as well as other aspects and advantages of the present invention will become apparent to those of ordinary skill in the art by reading the following detailed description, with appropriate reference to the accompanying drawings.

### BRIEF DESCRIPTION OF THE DRAWINGS

Presently preferred embodiments are described below in conjunction with the appended drawing figures, wherein like reference numerals refer to like elements in the various figures, and wherein:

FIG. 1 is a schematic drawing of a prior art method for reducing a high operating voltage applied to a transistor;

FIG. 2a is a schematic drawing of a circuit employing the method of reducing operating voltage in a p-MOS transistor in accordance with a first embodiment of the invention;

FIG. 2b is a schematic drawing of a circuit employing the method of reducing operating voltage in an n-MOS transistor in accordance with a second embodiment of the invention;

FIG. 3 is a schematic drawing of an output driver in accordance with a third embodiment of the invention; and

FIG. 4 is a schematic drawing of an output driver using an inverter and a level shift inverter employing the method for reducing too high on an operating voltage across a transistor in accordance with a fourth embodiment of the invention.

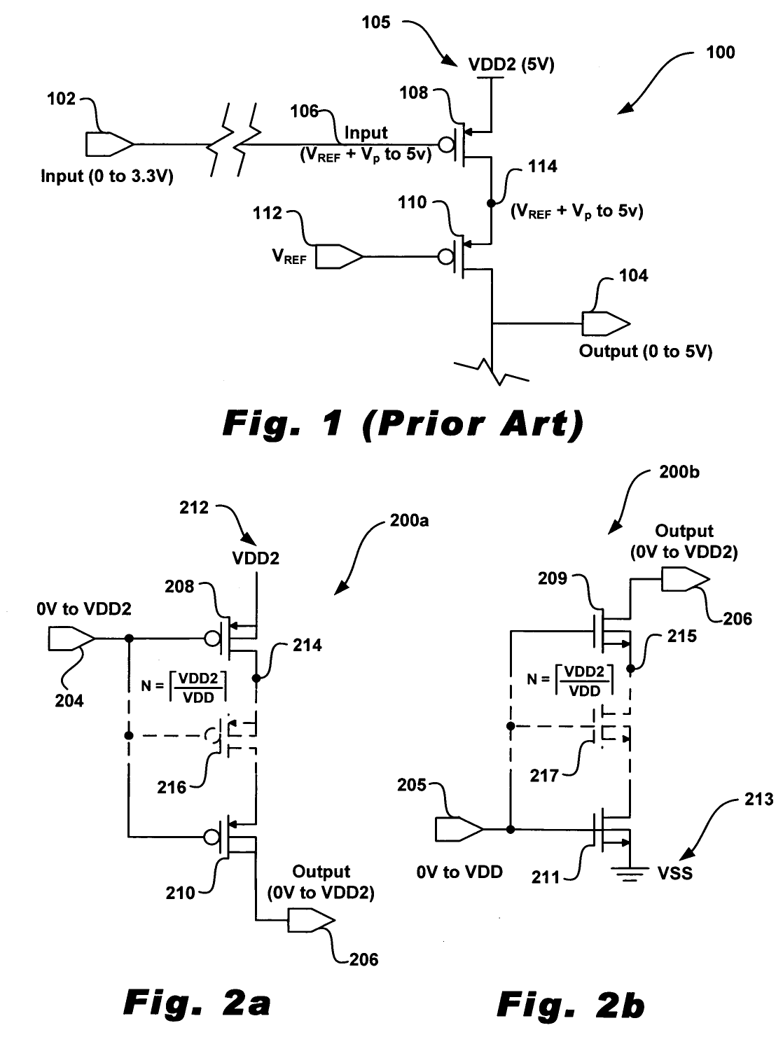

### DETAILED DESCRIPTION

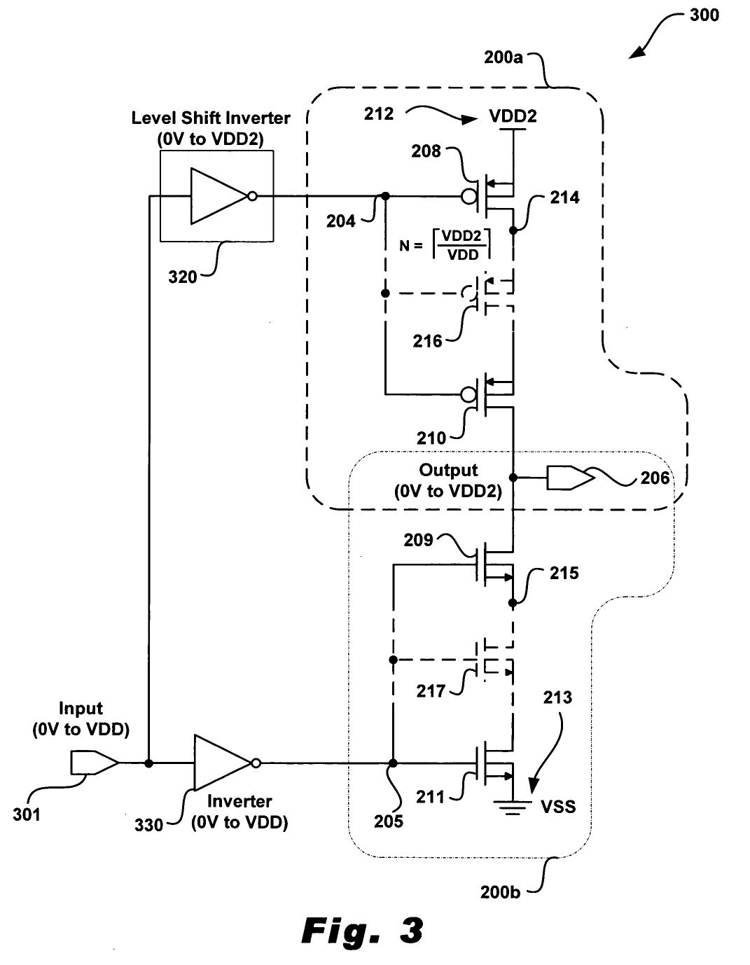

FIG. 2a is a schematic drawing of a voltage divider circuit 200a comprising a series of stacked p-MOS transistors. An input voltage 204 (0V or VDD2) is received by the circuit 200a and an output voltage 206, in response to the input 204 or additional circuitry, is output (0V or VDD2). The input 204 is fed into the gates of p-FET transistors 208 and 210. The source of p-MOS transistor 208 is connected to VDD2 212. If the voltage of the output 206 is at 0V, the voltage from the output 206 to VDD2 212 is effectively distributed across both transistors. That is, the voltage at node 214 is effectively half of VDD2 for identical p-MOS transistors. By tying both transistors together at their respective gates, an arbitrary voltage reference is not necessary to insure safe operating voltages across the transistors. Eliminating this reference voltage eliminates undesired current and heat dissipation that is typically caused by having at least one transistor always at least partially on.

In essence, when the input 204 is at a voltage level about equal to VDD2, both transistors 208 and 210 are off and the voltage drop across both transistors is evenly distributed. When the input goes to a low voltage, both transistors are on, but the voltage drop across both transistors still remains distributed across both transistors. One additional benefit is that the reduced voltage drop also provides reduced hot carrier effects when the devices are on. Also illustrated in FIG. 2a is the implementation of this configuration with existing as well as future technologies by application of Equation 1:

$$N = ⌈ \frac{VDD 2}{VDD} ⌉ \qquad Eq . 1$$

For example, if transistors with a 1.7 V operating voltage are desired to be integrated with a 5V operating voltage technology, by application of the above formula, the number, N, of necessary transistors would be three. A phantom p-MOS transistor 216 is shown between the transistors 208 and 210 to exemplify this application.

FIG. 2b is a schematic drawing of a voltage divider circuit 200b comprising a series of stacked n-MOS transistors. Similar to FIG. 2a, an input voltage 205 (0V or VDD) is received by the circuit and an output voltage 206, in response to the input 205 or additional circuitry, is output (0V or VDD2). Because the transistors are off when a voltage of 0V is applied to the input 205, the input voltage does not need to be at the higher operating voltage VDD2 to insure the transistors are off. Therefore, a level-shift inverter is not required. The input 205 is fed into the gates of n-FET transistors 209 and 211. The source of n-MOS transistor 211 is connected to a ground or common potential 213. If the voltage of the output 206 is at VDD2, the voltage from the output 206 to the common potential 213 is effectively distributed across both transistors. Again, the voltage at node 215 is effectively half of VDD2 if the n-MOS transistors are identical. Similar to the embodiment in FIG. 2, an arbitrary voltage reference is not necessary to ensure safe operating voltages across the transistors. As in the previous embodiment, the elimination of the reference voltage eliminates undesired current and heat. In addition, reduced hot carrier effects are also realized. If future designs require different operating voltages, Equation 1 can also be applied to determine the number of series transistors (as illustrated by the insertion of n-MOS transistor 217).

FIG. 3 is a schematic drawing of an output voltage driver circuit 300 comprising a series of stacked n-MOS and p-MOS transistors. An input 301, corresponding to a low voltage input (in the range of 0V to a low operating voltage value, VDD) is input into the output voltage driver circuit 300 and is translated into a higher operating voltage at the output 206 (in the range of 0V to a high operating voltage value, VDD2). That is, an input at input 301 with a voltage value of 0V will translate into a 0V output at 206 while an input of VDD will translate into a higher operating voltage output of VDD2.

The translation is carried out as follows: the input 301 is fed into a level shift inverter 320 and an inverter 330. The level shift inverter 320 inverts an input voltage to either 0V or VDD2 depending on the input (i.e. 0V at input 301 results in a VDD2 output of the level shift inverter and VDD at input 301 results in a 0V output of the level shift inverter). The output of the level shift inverter is input into the voltage divider circuit of FIG. 2a 200a at input 204. When the gates of p-MOS transistors 208 and 210 (as well as additional transistors if determined appropriate upon calculation of Equation 1) have a low input voltage at input 204 (i.e. 0V), the voltage divider circuit 200a pulls the output 206 to a level of VDD2 212. On the other side of the circuit, the output of the inverter 330 is input into the voltage divider circuit of FIG. 2b 200b at input 205. When the gates of n-MOS transistors 209 and 211 have an input voltage of VDD at input 205, the voltage divider circuit 200b pulls the output 206 to a level of the common potential 213 (i.e. 0V). And, like the voltage divider of FIG. 2b, additional n-MOS transistors can be added if necessary.

As mentioned above, the resultant output of the voltage divider circuits of FIG. 2a and FIG. 2b contribute to the resultant translation by using the respective outputs of the level shift inverter 320 as well as the inverter 330 to pull output 206 to either 0V or VDD2. Because of this, a voltage drop of approximately VDD2 will always exist across either the series p-MOS transistors of the divider circuit of FIG. 2a or the series n-MOS transistors of the divider circuit of FIG. 2b. However, each MOS transistor in the voltage divider circuits 200 and 200b will not be exposed to higher than operating voltages because the voltage is effectively distributed across all the transistors in each voltage divider circuit.

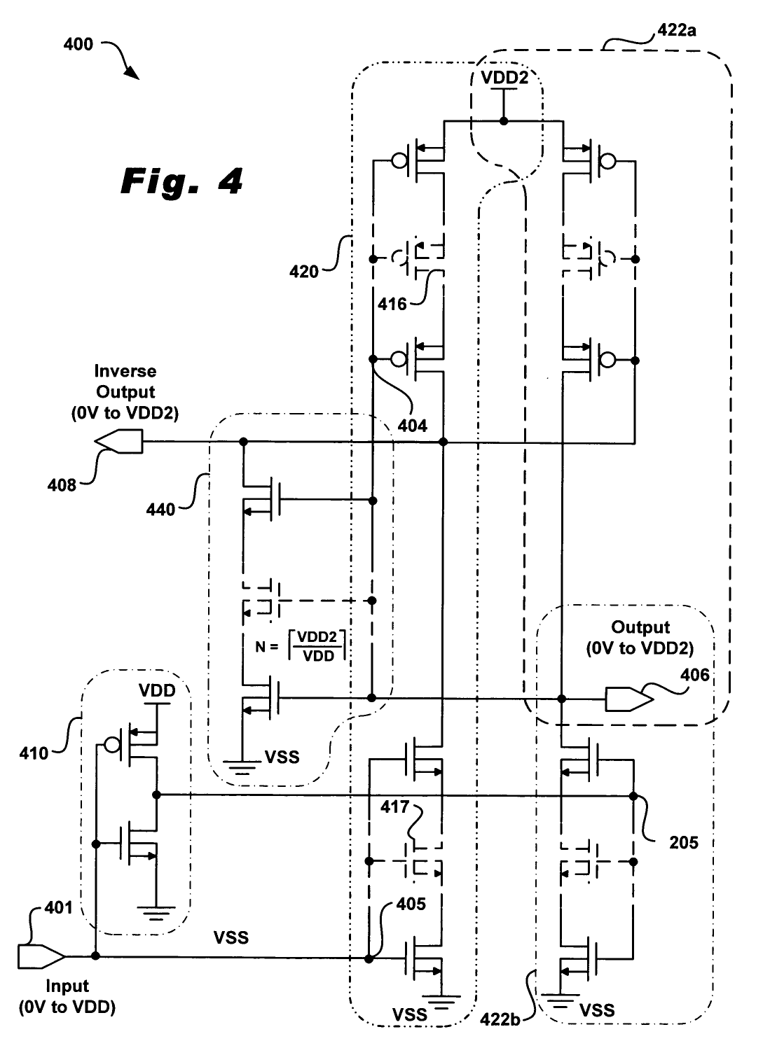

FIG. 4 is a schematic drawing of an output voltage driver circuit 400 comprising two divider circuits 200a and 200b, an inverter 330, as well as a level shift inverter 420. This circuit is similar and operates in a matter analogous to that of FIG. 3a. The input 301 is connected to the inverter 330 and the level shift inverter 420. The output of the inverter 330 is connected to the input node 205 of circuit 200b and the output of the level shift inverter 420 is connected to the input node 204 of circuit 200a and the output is taken at node 206 of both divider circuits 200a and 200b.

In this embodiment, however, the level shift inverter 420 is comprised of both p-MOS and n-MOS series stacked transistors. Essentially, the level shift inverter 420 employs the same circuit of FIG. 2a 200a and FIG. 2b 200b to minimize higher than rated voltages across any given transistor. Again, these stacked p-MOS and n-MOS transistors may contain more than two transistors (416 and 417 respectively) depending on the minimum and maximum operating voltage of the output voltage driver circuit 400. By distributing the VDD2 voltage across the series of p-MOS and n-MOS stacked transistors within the level shift inverter 420, higher than rated voltages are prevented from being applied across a single MOS transistor.

This particular embodiment employs a driver circuit 440, in order to force the output voltage 205 to a low value (0V) or a high value (VDD2). It should be understood, however, that this circuit is not essential and the gates of the n-MOS transistors at node 405 could be tied to the gates of the p-MOS transistors at node 404. For a circuit designer, it may also be advantageous to use the inverse voltage value of node 206. This can be realized by referencing the voltage at output node 450. Once more, this circuit can also be designed with multiple n-MOS transistors 418.

An embodiment of the present invention has been described above. Those skilled in the art will understand, however, that changes and modifications may be made to this embodiment without departing from the true scope and spirit of the present invention, which is defined by the claims.

We claim:

1. A voltage divider circuit, comprising:
a first input node at a first input voltage;
a second input node at a second input voltage;
an output node at an output voltage; and
at least two MOS transistors, connected in series by source-drain connections between each MOS transistor, the at least two MOS transistors each having a gate connected to the second input voltage, the at least two series connected MOS transistors including a first MOS transistor and a last MOS transistor, the first MOS transistor having a source connected to the first input voltage, the last MOS transistor having a drain connected to the output node, whereby a voltage difference between the first input voltage and the output node is distributed across the at least two MOS transistors.

2. The voltage divider circuit of claim 1, wherein the at least two MOS transistors are n-MOS transistors.

3. The voltage divider circuit of claim 1, wherein the at least two MOS transistors are p-MOS transistors.

4. The voltage divider circuit of claim 1, wherein the second voltage input is in the range of about 0V to a voltage less than the absolute value of the difference between the first input voltage and the output voltage.

5. The voltage divider circuit of claim 1, wherein the second input voltage further comprises an inverter having an inverter output.

6. The voltage divider circuit of claim 5, wherein the inverter output provides a voltage in a range of about 0V to a voltage less than the absolute value of the difference between the first input voltage and the output voltage.

7. An output voltage driver circuit, comprising:
a common voltage node at a voltage of about 0V;
a first input to provide a first input voltage;
a second input to provide a second input voltage at voltage in a range of about 0V to a voltage less than the first input voltage;
an output node at an output voltage;
a level shift inverter having an input and an output, the input of the level shift inverter receiving the second input voltage, the output of the level shift inverter being at a voltage in a range of about 0V to a voltage about equal to the first input voltage;
a plurality of series connected p-MOS transistors each having a gate connected to the output of the level shift inverter, the plurality of p-MOS transistors comprising a first p-MOS transistor and a second p-MOS transistor, the first p-MOS transistor having a source connected to the first input voltage, the second p-MOS transistor having a drain connected to the output node, whereby a voltage difference between the first input voltage and the output voltage is distributed across the plurality of series connected p-MOS transistors;
an inverter having an input and an output, the input of the inverter receiving the second input voltage, the output of the inverter being at a voltage in a range of about 0V to a voltage less than the first input voltage; and
a plurality of series-connected n-MOS transistors each having a gate connected to the output of the inverter, the plurality of n-MOS transistors comprising a first n-MOS transistor and a second n-MOS transistor, the first n-MOS transistor having a source connected to the common voltage node, the second n-MOS transistor having a drain connected to the output node, whereby a voltage difference between the common voltage node and the output voltage is distributed across the series of n-MOS transistors.

8. The output voltage driver circuit of claim 7, wherein the level shift inverter further comprises:
a second plurality of series-connected n-MOS transistors each having a gate connected to the input of the level shift inverter, the second plurality of n-MOS transistors comprising a third n-MOS transistor and a fourth n-MOS transistor, the third n-MOS transistor having a source connected to the common voltage node, the fourth n-MOS transistor having a drain connected to the output of the level shift inverter; and
a second plurality of series-connected p-MOS transistors each having a gate connected to the input of the level shift inverter, the second plurality of p-MOS transistors comprising a third p-MOS transistor and a fourth p-MOS transistor, the third p-MOS transistor having a source connected to the first input voltage, the fourth p-MOS transistor having a drain connected to the drain of the fourth n-MOS and the output of the level shift inverter.

9. The output voltage driver circuit of claim 8, wherein the second input voltage is between a minimum value and a maximum value, and wherein the inverter further comprises:
a third input to provide a third input voltage about equal to the maximum value of the second input voltage; and
a pair of complementary stacked transistors comprising a fifth p-MOS transistor and a fifth n-MOS transistor, the fifth p-MOS transistor each having a gate, a source, and a drain, the gate of the fifth p-MOS transistor connected to the input of the inverter, the source of the fifth p-MOS transistor connected to the third input voltage, the drain of the fifth p-MOS transistor connected to the drain of the fifth n-MOS transistor and the output of the inverter, the source of the fifth n-MOS transistor connected to the common voltage node, the gate of the fifth n-MOS transistor connected to the input of the inverter.

10. The output voltage driver circuit of claim 7, wherein the level shift inverter further comprises:
a second plurality of series-connected n-MOS transistors each having a gate connected to the input of the level shift inverter, the second plurality of n-MOS transistors comprising a third n-MOS transistor and a fourth n-MOS transistor, the third n-MOS transistor having a source connected to the common voltage node, the fourth n-MOS transistor having a drain;
a second plurality of series-connected p-MOS transistors each having a gate connected to the output node, the second plurality of PMOS transistors comprising a third p-MOS transistor and a fourth p-MOS transistor, the third p-MOS transistor having a source connected to the first input voltage, the fourth p-MOS transistor having a drain connected to the drain of the fourth n-MOS transistor; and
a third plurality of series-connected n-MOS transistors each having a gate connected to the output node and the gates of the second series of p-MOS transistors, the third plurality of n-MOS transistors comprising a fifth n-MOS transistor and a sixth n-MOS transistor, the fifth n-MOS transistor having a source connected to the common voltage node, the sixth-MOS transistor having a drain connected to the drain of the fourth p-MOS transistor.

11. The output voltage driver circuit of claim 10, wherein the level shift inverter further comprises an inverse output node connected to the drain of the fourth n-MOS transistor.

12. The output voltage driver circuit of claim 10, wherein the second input voltage is between a minimum value and a maximum value, and wherein the inverter further comprises:
a third input to provide a third input voltage having a voltage about equal to the maximum value of the second input voltage; and
a pair of complementary stacked transistors comprising a seventh p-MOS transistor and a seventh n-MOS transistor each having a gate, a source, and a drain, the gate of the seventh p-MOS transistor connected to the input of the inverter, the source of the seventh p-MOS transistor connected to the third input voltage, the drain of the seventh p-MOS transistor connected to the drain of the seventh n-MOS transistor and the output of the inverter, the source of the seventh n-MOS transistor connected to the common voltage input, the gate of the seventh n-MOS transistor connected to the input of the inverter.

13. The output voltage driver circuit of claim 12, wherein the level shift inverter further comprises an inverse output node connected to the drain of the fourth n-MOS transistor.

14. A method for reducing a higher than rated operating voltage across a MOS transistor, the method comprising:
calculating a quantity of MOS transistors by dividing a ceiling function of a high rated operating voltage by a low operating voltage;
connecting in series the quantity of MOS transistors, the quantity of MOS transistors including a first MOS transistor and a last MOS transistor, each having a source and a drain;
supplying a shared gate voltage to each MOS transistor; and
applying the high rated operating voltage across the drain of the last MOS transistor and the source of the first MOS transistor in the series of MOS transistors, thereby distributing the high rated voltage amongst the quantity of MOS transistors.
